(19) United States
(12) Patent Application Publication
(10) Pub. No.: US 2009/0267703 A1
(43) Pub. Date: Oct. 29, 2009

(54) DYNAMICALLY ADAPTABLE IMPEDANCE MATCHING CIRCUITRY BETWEEN AN ELECTRO-OPTICAL LOAD AND A DRIVING SOURCE

(76) Inventors: Andrzej May, Schenectady, NY (US); Siavash Yazdanfar, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 12/108,009

(22) Filed: Apr. 23, 2008

(51) Int. Cl. H03H 7/38

(52) U.S. Cl. 333/32

(57) ABSTRACT

A system including a driving source that supplies an alternating current (AC) electrical signal is provided. At least one electro-optical device is coupled as an electrical load of the driving source. The system further includes an apparatus configured to provide a dynamically adaptable electrical impedance matching between the driving source and the electro-optical load over a frequency range.

### STATEMENT OF GOVERNMENT RIGHTS

The United States Government may have certain rights in this invention pursuant to contract number 1 U54 CA119367-01 awarded by the National Cancer Institute of the National Institutes of Health.

### FIELD OF THE INVENTION

Embodiments of the present invention are generally related to electro-optical (EO) devices and systems that may employ such EO devices, and, more particularly, to a dynamically adaptable impedance matching circuitry between an electro-optical load and a driving source.

### BACKGROUND OF THE INVENTION

Electro-optical (EO) devices, such as electro-optical modulators, electro-optical gates, photomultiplier tubes, image intensifiers, Kerr cells, Pockels cells, etc., can change their optical properties when subjected to an electric field. For example, an EO modulator may require radio-frequency (RF) control voltages that may range from 100 V to 3000 V to provide substantial modulating performance. The electrical load presented by the EO device to a driving electrical source (e.g., having a 50 ohm impedance) is mostly capacitive with a reactance that may range from 10 pF to 200 pF, which, at typical operating radio-frequencies (e.g., >1 MHz), can lead to electrical impedance values of much less than 50 ohms (reactive load) with respect to the driving source.

The foregoing characteristics of the EO load can lead to considerable impedance mismatch between the driving source and the EO load and can result in substantial electrical current being drawn from the driving source and can greatly increase the power requirements for the driving source compared to a relatively low-frequency modulation of the same EO device. Accordingly, it is desirable to provide improved circuitry, such as a compact, reliable, and relatively inexpensive circuitry, that reduces or avoids the above-discussed issues by providing impedance match between the EO load and the driving source across a wide range of operational conditions.

### BRIEF DESCRIPTION OF THE INVENTION

Generally, aspects of the present invention provide an apparatus configured to provide dynamically adaptable electrical impedance matching. The apparatus includes a driving source configured to supply an alternating current (AC) electrical signal. The apparatus further includes an adjustable impedance matching network connected to receive the electrical signal from the driving source and output a corresponding driving electrical signal. An electro-optical device is responsive to the driving signal from the adjustable impedance matching network. The driving signal is operable at a selectable frequency over a frequency range and is configured to control an optical property of the electro-optical device. A monitor is configured to monitor one or more parameters indicative of an electrical impedance imbalance that can occur between the driving source and the electro-optical device during an operational condition. A processor is configured to determine an adjustment to the impedance matching network to reduce the electrical impedance imbalance between the driving source and the electro-optical device.

Further aspects of the present invention provide a system including a driving source configured to supply an alternating current (AC) electrical signal. At least one electro-optical device is coupled as an electrical load of the driving source. The system further includes an apparatus configured to provide a dynamically adaptable electrical impedance matching between the driving source and the electro-optical load.

### BRIEF DESCRIPTION OF THE DRAWINGS

FIG. 1 is a block diagram representation of an apparatus configured to provide dynamically adaptable impedance-matching to an electro-optical (EO) device with respect to the impedance characteristics of a driving electrical source.

FIG. 2 provides example circuitry details in one example embodiment for the apparatus of FIG. 1.

FIG. 3 shows respective plots of example variation as may occur in the impedance magnitude of an unmatched EO load as a function of frequency compared to an essentially flat variation in the impedance of a matched EO load in accordance with aspects of the present invention.

### DETAILED DESCRIPTION OF THE INVENTION

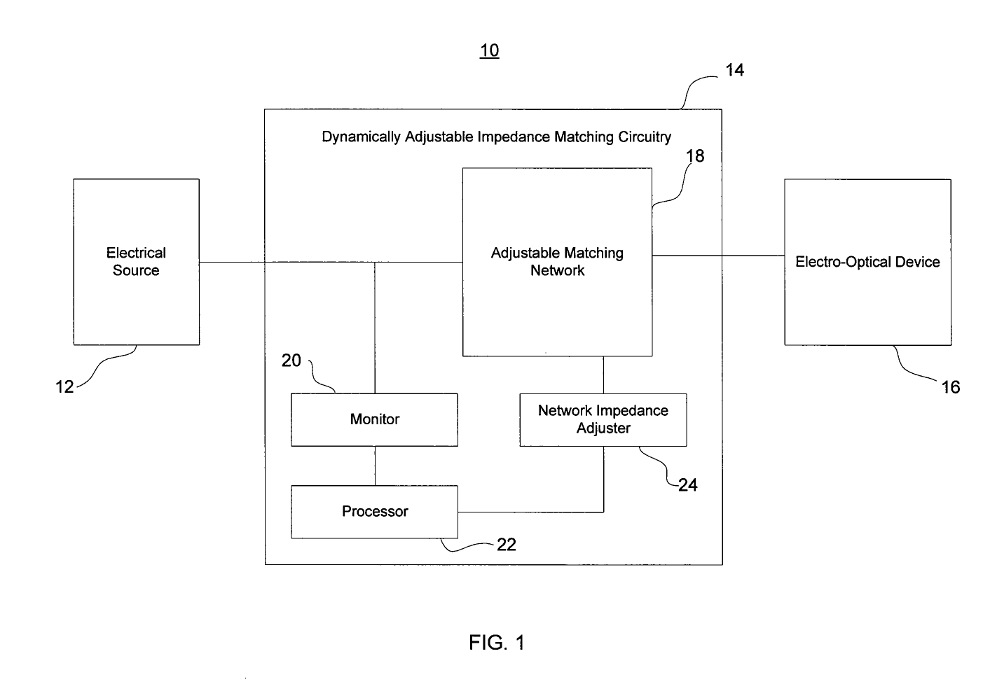

FIG. 1 is a block diagram representation of an apparatus 10 that may be a component of a system, such as a medical imaging system, camera, night-vision system, optical communication system, etc., where an electro-optical device 16 (also referred to throughout this description as the EO load) is responsive to an applied electrical signal to selectively control its electro-optical properties. By way of example and not of limitation, the electro-optical device 16 may be an electro-optical modulator, an electro-optical gate, a photomultiplier tube, an image intensifier, a Kerr cell, a Pockels cell, etc. For readers desirous of general background information regarding EO devices, reference is made to chapter 18 of textbook titled “Fundamental of Photonics” by B. E. A. Saleh and M. C. Teich, copyright ©1991 by John Wiley & Sons, Inc., and for readers desirous of general background information regarding imaging system modalities reference is made to chapter 4 (“Modalities and Methods” by Hans-Jergen Smith) of textbook titled “NICER Centennial Book 1995—A Global Textbook of Radiology”, each of such chapters is respectively herein incorporated by reference.

The inventors of the present invention have recognized relatively inexpensive and straightforward impedance-matching circuitry 14 that advantageously allows in a dynamically adaptable manner to match over a wide frequency range the load impedance of the EO device with respect to the impedance characteristics of an alternating current (AC) electrical driving source 12, e.g., a radio frequency (RF) source. In one example embodiment, the value of the frequency of the output signal from electrical driving source may be in a range from 0.01 MHz to 20 GHz.

Circuitry 14 includes an adjustable matching network 18, such as a L-type, Pi-type, T-type, or a combination of at least two of such types of matching networks, made up of inductor (L) and capacitor (C) components electrically interconnected to receive as an input the electrical signal from electrical source 12 and further coupled to provide as an output the electrical signal applied to control the optical properties of the EO device. Adjustable matching network 18 provides suitable signal conditioning (e.g., a voltage step-up from 20 dB to 40 dB or more) to the signal from electrical source 12, without a corresponding increase in the ratings of electrical source 12. An example of a commercially available circuitry that may be adapted to implement EO impedance-matching circuitry 14 may be antenna coupler circuitry available from SGC Inc., Bellevue, Wash., U.S.A.

Matching network 18 is configurable to virtually transform the load impedance of EO device 16 to a value commensurate with the impedance characteristics of electrical source 12. Circuitry 14 further includes a monitor 20 configured to monitor essentially in real time one or more parameters indicative of electrical load imbalances that can arise due to various conditions, such as due to changes in environmental conditions and/or operational conditions (e.g., changes in the frequency of the electrical signal applied to the EO load) as may be desired for a given application of the system. For example, in the case of fluorescence imaging, it may desirable to adjust the frequency of the electrical signal being applied to an image intensifier depending on the specific agent (e.g., fluorophore stain) being used to develop fluorescence.

In one example embodiment, monitor 20 may be an RF power meter configured to monitor forward power and reflected power when RF power is applied to the EO device through the adjustable matching network. As will be appreciated by one skilled in the art, appropriate impedance matching would result in essentially no power reflections, which is desirable to effectively transfer power to the EO load. In another example embodiment, monitor 20 may be configured to monitor the impedance of the EO device (e.g., reactive impedance) when RF power is applied to the EO device through the adjustable matching network, such as may be inferred by monitoring a phase shift in the RF signal. In yet another example embodiment, monitor 20 may be configured to monitor a voltage standing-wave ratio (VSWR) that results when RF power is applied to the EO device through the adjustable matching network. For readers desirous of general background information regarding impedance matching schemes reference is made to chapter 10 of textbook titled “Engineering Electromagnetic Fields and Waves” by Carl T. A. Johnk, copyright © 1975 by John Wiley and Sons, Inc., which chapter is herein incorporated by reference.

In each case, monitor 20 is coupled to a processor 22 (e.g., a microprocessor) to supply the monitored parameter/s indicative of the electrical load imbalance that can arise between RF source 12 and EO device 16. Processor 22 is configured with a suitable algorithm or look-up table to calculate the L and C component values that would allow matching network 18 to match the load impedance of EO device 16 with the characteristics of electrical source 12 for any changing operational condition.

Processor 22 is further configured to drive a network impedance adjuster 24 connected to matching network 18 to adjust the respective L and C component values of the matching network 18 so that an impedance match is achieved between electrical source 12 and EO device 16. The network impedance adjuster 24 may include one or more arrays of capacitors and inductors selectively connectable to provide a desired adjustment value (e.g., binary incremental values) to the respective L and C components of the matching network 18.

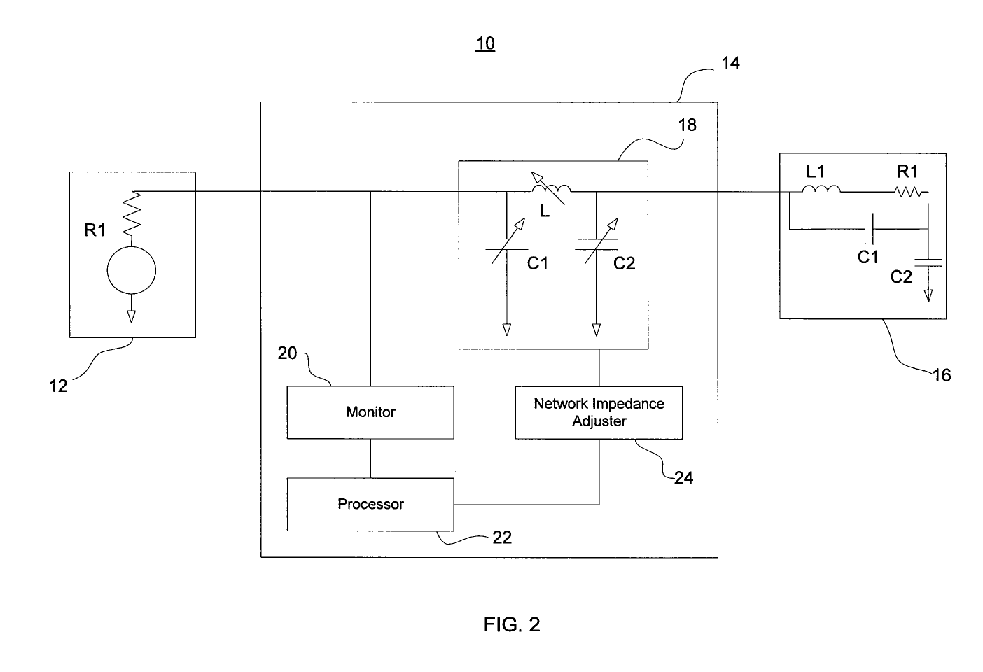

FIG. 2 provides circuitry details for one example embodiment of apparatus 10. In this example embodiment, electrical source comprises a 50 ohm R1 impedance. In this example embodiment, matching network 18 comprises a Pi network where respective values of capacitors C1 and C2 may range from 50 pF to 500 pF and the values of inductor L may range from 1 μH to 500 μH. In this example embodiment, EO device 16 may be an image intensifier that may be modeled with the illustrated circuit representation, where inductor L1 may have a value of 76 nH, resistor R1 may have a value of 1.5 ohm, capacitor C1 may have a value of 3 pF and capacitor C2 may have a value of 35 pF. It will be appreciated that the present invention is in no way limited either to the circuit topologies shown in FIG. 2 or to the component values described above since many other circuit implementations will equally benefit from an apparatus embodying aspects of the present invention.

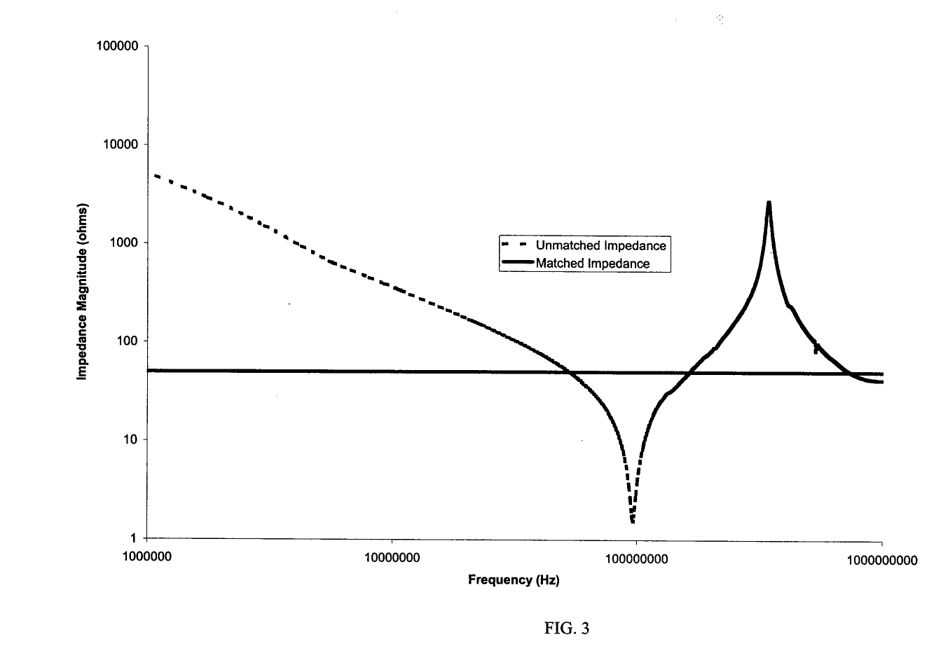

FIG. 3 shows respective plots of example variation in the impedance magnitude of an unmatched EO device (dashed-line plot) as a function of frequency compared to an essentially flat variation (solid-line plot) in the magnitude of the impedance of a matched EO device in accordance with aspects of the present invention.

In operation an apparatus embodying aspects of the present invention is expected to provide one or more of the example advantages listed below:
a. reducing the power and/or voltage ratings of the RF source that drives the EO device load over a wide range of frequencies. For example, in a matched condition, it is contemplated that the power and/or voltage requirements for the electrical source can be reduced by as much as 20 dB and 40 dB respectively, resulting in a more compact, reliable and less expensive apparatus than previous apparatuses;
b. enabling a relatively fast and dynamically adaptable impedance matching between the EO device and the electrical source and this in turn is conducive to being able to adjust the frequency of the RF signal applied to the EO device to control its electro-optical properties, as may be desired to optimize the performance of the EO device for a given system application;
c. systematically reducing variation in the electro-optical performance of the electrical device over a wide range of operational frequencies;
d. permitting use of transmission line cabling that may substantially vary in length between the electrical source and EO device without introducing undesirable degradation in performance due to substantial variation in the intrinsic impedance of such a cabling; and
e. circuitry that is substantially impervious to variations that may occur in the impedance of the EO device itself, such as lot impedance variation that may occur from one EO device to another EO device, or impedance variation that may occur for a given EO device, as a function of aging or changes in environmental conditions.

While certain embodiments of the present invention have been shown and described herein, such embodiments are provided by way of example only. Numerous variations, changes and substitutions will occur to those of skill in the art without departing from the invention herein. Accordingly, it is intended that the invention be limited only by the spirit and scope of the appended claims.

What is claimed is:

1. Apparatus configured to provide dynamically adaptable electrical impedance matching, said apparatus comprising:
a driving source configured to supply an alternating current (AC) electrical signal;
an adjustable impedance matching network connected to receive the electrical signal from the driving source and output a corresponding driving electrical signal;
an electro-optical device responsive to the driving signal from the adjustable impedance matching network, said driving signal operable at a selectable frequency over a frequency range and configured to control an optical property of the electro-optical device;
a monitor configured to monitor one or more parameters indicative of an electrical impedance imbalance that can occur between the driving source and the electro-optical device during an operational condition; and
a processor configured to determine an adjustment to the impedance matching network to reduce the electrical impedance imbalance between the driving source and the electro-optical device.

2. The apparatus of claim 1 wherein the impedance matching network is a network selected from the group consisting of a L-type, a Pi-type, a T-type and a combination of at least two of said type of networks.

3. The apparatus of claim 1 further comprising a network impedance adjuster connected to adjust a value of at least one of an inductor component and a capacitor component in the impedance matching network, the adjustment being performed in response to an adjustment command from the processor to reduce the electrical impedance imbalance between the driving source and the electro-optical device.

4. The apparatus of claim 1 wherein the electro-optical device is selected from the group consisting of an electro-optical modulator, an electro-optical gate, a photomultiplier tube, an image intensifier, a Kerr cell, and a Pockels cell.

5. The apparatus of claim 1, wherein said apparatus is a component of a system selected from the group consisting of an imaging system, a camera system, a night-vision system, and an optical communication system.

6. The apparatus of claim 1, wherein said apparatus is a component of a fluorescence imaging system, wherein said electro-optical device is an image intensifier, wherein the frequency of the driving signal applied to the image intensifier is adjustable based on an fluorescent agent used by said fluorescence imaging system.

7. The apparatus of claim 1, wherein the frequency range of the driving signal applied to the electro-optical device ranges from 0.01 MHz to 20 GHz.

8. A system comprising:
a driving source configured to supply an alternating current (AC) electrical signal;
at least one electro-optical device coupled as an electrical load of the driving source; and
apparatus configured to provide a dynamically adaptable electrical impedance matching between said driving source and the electro-optical load.

9. The system of claim 8, wherein said apparatus comprises:
an adjustable impedance matching network connected to receive the electrical signal from the driving source and output a corresponding driving electrical signal, said driving signal operable at a selectable frequency over a frequency range and configured to control an optical property of the electro-optical device;
a monitor configured to monitor one or more parameters indicative of an electrical impedance imbalance that can occur between the driving source and the electro-optical device during an operational condition; and
a processor configured to determine an adjustment to the impedance matching network to reduce the electrical impedance imbalance between the driving source and the electro-optical device.

10. The system of claim 1 wherein the impedance matching network is a network selected from the group consisting of a L-type, a Pi-type, a T-type and a combination of at least two of said type of networks.

11. The system of claim 8 further comprising a network impedance adjuster connected to adjust a value of at least one of an inductor component and a capacitor component in the impedance matching network, the adjustment being performed in response to an adjustment command from the processor to reduce the electrical impedance imbalance between the driving source and the electro-optical device.

12. The system of claim 8 wherein the electro-optical device is selected from the group consisting of an electro-optical modulator, an electro-optical gate, a photomultiplier tube, an image intensifier, a Kerr cell, and a Pockels cell.

13. The system of claim 1, wherein said system is selected from the group consisting of an imaging system, a camera system, a night-vision system, and an optical communication system.

14. The system of claim 8, wherein said system comprises a fluorescence imaging system, wherein said electro-optical device is an image intensifier, wherein the frequency of the driving signal applied to the image intensifier is adjustable based on a fluorescent agent used by said fluorescence imaging system.

15. The system of claim 9, wherein the frequency range of the driving signal applied to the electro-optical device ranges from 0.1 MHz to 20 GHz.
